(19) United States
(12) Patent Application Publication
(10) Pub. No.: US 2026/0190797 A1
(43) Pub. Date: Jul. 2, 2026

(54) Display Device

(71) Applicant: LG Display Co., Ltd., Seoul (KR)

(72) Inventors: Insu Hwang, Seoul (KR); Soyoon Moon, Seoul (KR)

(21) Appl. No.: 19/428,844

(22) Filed: Dec. 22, 2025

(30) Foreign Application Priority Data
Dec. 31, 2024 (KR) 10-2024-0202062

(51) Int. Cl. H10K 59/80; H10K 59/122; H10K 59/124; H10K 59/131; H10K 59/88

(52) U.S. Cl. CPC H10K 59/874; H10K 59/122; H10K 59/124; H10K 59/131; H10K 59/873; H10K 59/88

(57) ABSTRACT

A display device according to the present disclosure includes a substrate divided into a display area and a non-display area, an inorganic insulating layer and a planarization layer disposed over the substrate, a light emitting element disposed over the planarization layer and comprising an anode, an organic layer, and a cathode, an outer dam disposed over the substrate in the non-display area so as to enclose the display area, a plurality of inner dams disposed in the display area and a back cover which maintains a gap by the outer dam and the inner dam and is vacuum-bonded to the substrate, and a bonding layer and an encapsulation substrate required for an encapsulation can be eliminated, thereby reducing the consumption of raw materials for the bonding layer and the encapsulation substrate, and reducing process costs by omitting of a process for encapsulation.

### CROSS-REFERENCE TO RELATED APPLICATIONS

This application claims the priority under 35 U.S.C. § 119(a) to the Republic of Korea Patent Application No. 10-2024-0202062 filed on Dec. 31, 2024, the entire contents of which are hereby expressly incorporated by reference into the present application.

### TECHNICAL FIELD

The present disclosure relates to a display device, and more particularly, to a display device having an encapsulation structure that prevents moisture permeation.

### BACKGROUND

Currently, as it enters a full-fledged information era, the field of display devices that visually display electrical information signals is rapidly developing, and research is being conducted to develop performances such as thinning, weight reduction, and low power consumption for various display devices.

Representative examples of display devices include a liquid crystal display (LCD) device an electro-wetting display (EWD) device, and an organic light emitting display (OLED) device.

Among them, an electroluminescent display device including an organic light emitting display device is a self-emitting display device and does not require a separate light source unlike a liquid crystal display device, and thus may be manufactured to have a light weight and a small thickness. In addition, the electroluminescent display device is advantageous not only in terms of power consumption because the electroluminescent display device operates at a low voltage, but also in terms of color implementation, a response speed, a viewing angle, and a contrast ratio (CR), so it is expected to be utilized in various fields.

For such electroluminescent display devices, it is very important to protect a light emitting element from moisture and oxygen permeation in order to improve reliability and lifespan. Therefore, research on encapsulation technology for protecting the light emitting element from moisture and oxygen permeation has been continuously conducted.

### SUMMARY

An object to be achieved by the present disclosure is to provide a display device capable of protecting a light emitting element from moisture and oxygen permeation while minimizing a thickness of an encapsulation layer.

Another object to be achieved by the present disclosure is to provide a display device capable of reducing the consumption of raw materials and process costs by omitting an adhesive layer and an encapsulation substrate.

Still another object to be achieved by the present disclosure is to provide a display device capable of blocking the propagation of cracks in a protective layer caused by a desiccant in an inner dam.

Objects of the present disclosure are not limited to the above-mentioned objects, and other objects, which are not mentioned above, can be clearly understood by those skilled in the art from the following descriptions.

A display device according to an exemplary embodiment of the present disclosure may include a substrate divided into a display area and a non-display area, an inorganic insulating layer and a planarization layer disposed over the substrate, a light emitting element disposed over the planarization layer and comprising an anode, an organic layer, and a cathode, an outer dam disposed over the substrate in the non-display area to surround the display area, a plurality of inner dams disposed in the display area, and a back cover which maintains a gap by the outer dam and the inner dam and is vacuum-bonded to the substrate.

Other detailed matters of the embodiments are included in the detailed description and the drawings.

In some embodiments, a dam is provided at the edge and inside of the display panel, and the display panel is sealed through the dam and the back cover. As a result, the adhesive layer and the encapsulation substrate required for the encapsulation can be eliminated, thereby reducing the consumption of raw materials for the adhesive layer and the encapsulation substrate and reducing the process cost by omitting the process for encapsulation. In addition, by removing the adhesive layer and the encapsulation substrate, the thickness of the encapsulation layer can be minimized compared to conventional encapsulation structure, while still protecting the light-emitting element from moisture and oxygen penetration.

According to the present disclosure, by forming a disconnection structure on the substrate corresponding to the inner dam, the propagation of cracks in the protective layer caused by the desiccant in the inner dam can be blocked. This prevents oxygen or moisture from penetrating into the light emitting element, thereby improving the reliability of the display panel and extending the lifespan of the light emitting element. In addition, power consumption may be reduced, which in turn reduces the use of fossil fuels for power generation, thereby lowering greenhouse gas emissions, contributing to the implementation of environment, social, and governance (ESG) objectives.

The effects according to the present disclosure are not limited to the contents exemplified above, and more various effects are included in the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a block diagram of a display device according to a first embodiment of the present disclosure.

FIG. 2 is a circuit diagram of a subpixel of the display device according to the first embodiment of the present disclosure.

FIG. 3 is a plan view of a display device according to the first embodiment of the present disclosure.

FIG. 4 is a cross-sectional view taken along the line I-I′ of FIG. 3.

FIG. 5 is a cross-sectional view taken along the line II-II′ of FIG. 3.

FIG. 6 is a cross-sectional view of one subpixel.

FIG. 7 is a plan view of a display device according to a second embodiment of the present disclosure.

FIG. 8 is a plan view of a display device according to a third embodiment of the present disclosure.

FIG. 9 is a cross-sectional view taken along the line III-III′ of FIG. 8.

FIG. 10 is a cross-sectional view of a display device according to a fourth embodiment of the present disclosure.

FIG. 11 is a cross-sectional view illustrating another example of a display device according to the fourth embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, exemplary embodiments of the present disclosure will be described in detail with reference to accompanying drawings.

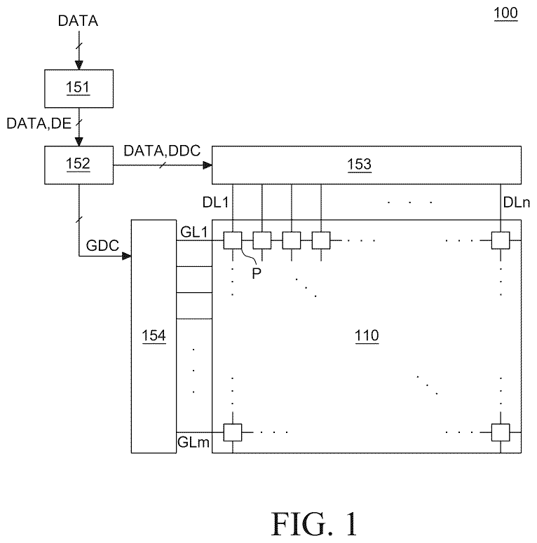

FIG. 1 is a block diagram of a display device according to a first embodiment of the present disclosure.

Referring to FIG. 1, a display device 100 according to a first embodiment of the present disclosure may include an image processor 151, a timing controller 152, a data driver 153, a gate driver 154, and a display panel 110.

The image processor 151 may output a data signal DATA, a data enable signal DE, and the like through a data signal DATA supplied from an outside.

The image processor 151 may output one or more of a vertical synchronization signal, a horizontal synchronization signal, and a clock signal in addition to the data enable signal DE.

The timing controller 152 is supplied with the data signal DATA together with a data enable signal DE or a driving signal including the vertical synchronization signal, the horizontal synchronization signal, and the clock signal from the image processor 151. The timing controller 152 may output a gate timing control signal GDC for controlling an operation timing of the gate driver 154 and a data timing control signal DDC for controlling an operation timing of the data driver 153 based on the driving signal.

Further, the data driver 153 samples and latches the data signal DATA supplied from the timing controller 152 in response to the data timing control signal DDC supplied from the timing controller 152 to convert the data signal into a gamma reference voltage and output the converted gamma reference voltage. The data driver 153 may output the data signal DATA through data lines DL1 to DLn.

Further, the gate driver 154 may output a gate signal while shifting a level of the gate voltage in response to the gate timing control signal GDC supplied from the timing controller 152. The gate driver 154 may output the gate signal through gate lines GL1 to GLm.

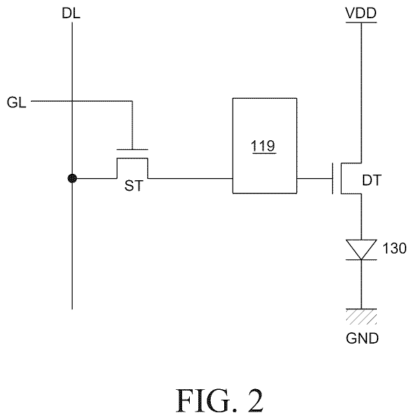

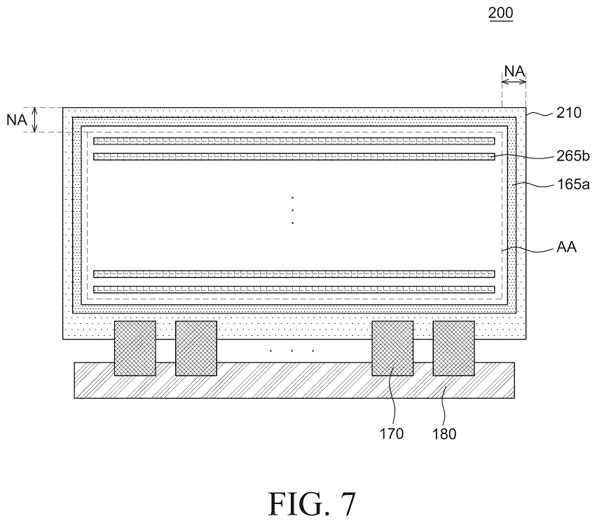

The display panel 110 may display an image while a subpixel P emits light in response to the data signal DATA and the gate signal supplied from the data driver 153 and the gate driver 154. A detailed structure of the subpixel P will be described with reference to FIGS. 2 and 7.

FIG. 2 is a circuit diagram of a subpixel of the display device according to the first embodiment of the present disclosure.

Referring to FIG. 2, a subpixel of a display device according to the first embodiment of the present disclosure may include a switching transistor ST, a driving transistor DT, a compensation circuit 119, and a light emitting element 130.

The light emitting element 130 may operate to emit light according to a driving current formed by the driving transistor DT.

The switching transistor ST may perform a switching operation such that a data signal supplied through a data line DL is stored in a capacitor as a data voltage in response to a gate signal supplied through a gate line GL.

In addition, the driving transistor DT may operate such that a constant driving current flows between the high potential power line VDD and the low potential power line GND in response to the data voltage stored in the capacitor.

The compensation circuit 119 is a circuit for compensating for a threshold voltage, etc. of the driving transistor DT, and the compensation circuit 119 may include one or more thin film transistors and capacitors. The configuration of the compensation circuit 119 may vary depending on a compensation method.

For example, the subpixel illustrated in FIG. 2 is configured by a 2T(transistor)1C(capacitor) including a switching transistor ST, a driving transistor DT, a capacitor, and a light emitting element 130. However, when the compensation circuit 119 is added, the subpixel may be configured in various forms, such as 3T1C, 4T2C, 5T2C, 6T1C, 6T2C, 7T1C, and 7T2C.

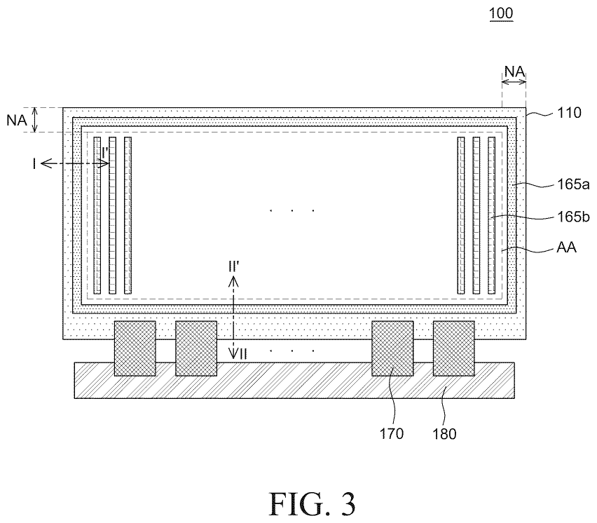

FIG. 3 is a plan view of a display device according to the first embodiment of the present disclosure.

In FIG. 3, for the convenience of description, a back cover disposed over the display panel is omitted.

Referring to FIG. 3, the display device 100 according to the first embodiment of the present disclosure may include a display panel 110, a flexible film 170, and a printed circuit board 180.

The display panel 110 is a panel for displaying an image to a user.

The display panel 110 may include a display element configured to display images, a driving element configured to operate the display element, and wirings configured to transmit various signals to the display element and the driving element. The display element may be differently defined depending on the type of the display panel 110, and for example, when the display panel 110 is an organic light emitting display panel, the display element may be an organic light emitting element including an anode, an organic light emitting layer, and a cathode.

Hereinafter, even though it is assumed that the display panel 110 is an organic light emitting display panel, the display panel 110 is not limited to the organic light emitting display panel.

The display panel 110 may include a display area AA and a non-display area NA.

The display area AA is an area in which images are displayed on the display panel 110.

In the display area AA, a plurality of subpixels constituting a plurality of pixels and a circuit for driving the plurality of subpixels may be disposed. The plurality of subpixels is minimum units constituting the display area AA, and a display element may be disposed in each of the plurality of subpixels, and the plurality of subpixels may constitute a pixel. For example, an organic light emitting element including an anode, an organic emission layer, and a cathode may be disposed in each of the plurality of subpixels, and it is not limited thereto. Further, a circuit for driving the plurality of subpixels may include a driving element, a wiring, and the like. For example, the circuit may be formed of a thin film transistor, a storage capacitor, a gate line, a data line, or the like, and is not limited thereto.

The non-display area NA is an area where an image is not displayed.

FIG. 3 illustrates that the non-display area NA encloses the display area AA having a rectangular shape. However, the shapes and arrangements of the display area AA and the non-display area NA are not limited to the example illustrated in FIG. 3.

In addition, the display area AA and the non-display area NA may have shapes suitable for the design of an electronic device equipped with the display device 100. For example, another exemplary shape of the display area AA may be a pentagon, a hexagon, a circle, an oval, or the like.

In the non-display area NA, various wirings and circuits for driving the organic light emitting element of the display area AA may be disposed. For example, in the non-display area NA, a link line for transmitting signals to the plurality of subpixels and circuits of the display area AA or a driving IC such as a gate driver IC or a data driver IC may be disposed, and it is not limited thereto.

Meanwhile, the left and right sides of FIG. 3 may be defined as gate pad parts on which the gate driver IC is disposed, and the lower side of FIG. 3 may be defined as a data pad part connected to the flexible film 170, and are not limited thereto.

The gate driver IC may be independently formed from the display panel 110 to be electrically connected to the display panel 110 in various ways, but may also be configured in a gate-in-panel (GIP) manner mounted in the display panel 110.

The display device 100 may include various additional elements for generating various signals or driving pixels in the display area AA. Additional elements for driving the pixel may include an inverter circuit, a multiplexer, an electrostatic discharge (ESD) circuit, and the like. The display device 100 may also include additional elements related to functions other than pixel driving. For example, the display device 100 may include additional elements that provide a touch sensing function, a user authentication function (e.g., fingerprint recognition), a multi-level pressure sensing function, a tactile feedback function, and the like. This additional element may be located in an external circuit connected to the non-display area NA and/or the connection interface.

Further, the flexible film 170 is a film for supplying a signal to the plurality of subpixels and circuits of the display area AA and may be electrically connected to the display panel 110. The flexible film 170 may be disposed at one end of the non-display area NA of the display panel 110 to supply a power voltage, a data voltage, and the like to the plurality of subpixels and the circuit of the display area AA. For example, a driving IC such as a data driver IC may be disposed on the flexible film 170.

The printed circuit board 180 may be disposed at one end of the flexible film 170 to be connected to the flexible film 170. The printed circuit board 180 is a component that supplies signals to the driving IC. The printed circuit board 180 may supply various signals such as a driving signal and a data signal to the driving IC.

Meanwhile, the display device 100 needs an encapsulation structure for protecting the light emitting element from moisture and oxygen permeation. Conventionally, a display panel is sealed using an adhesive layer and an encapsulation substrate, the adhesive layer serves to delay lateral moisture permeation, and the encapsulation substrate, together with the adhesive layer, serves to protect the light emitting element from external moisture, oxygen, impact, and the like. Thereafter, in the module process, the back cover is attached to the top of the encapsulation substrate. At this time, the encapsulation substrate overlaps in function with the back cover, and is mainly made of stainless steel (SUS) or Invar, resulting in additional costs. In addition, since a process of laminating the encapsulation substrate to the display panel via the adhesive layer is required, the overall process cost is increased.

Accordingly, in the first embodiment of the present disclosure, dams 165a and 165b are provided at the edges and inside of the display panel 110, and the display panel 110 is sealed through the dams 165a and 165b and the back cover. Therefore, the adhesive layer and the encapsulation substrate required for the encapsulation can be eliminated, thereby reducing the consumption of raw materials for the adhesive layer and the encapsulation substrate, and reducing the process cost by omitting the process for encapsulation. In addition, the removing of the adhesive layer and the encapsulation substrate, the thickness of the encapsulation layer can be minimized compared to the conventional encapsulation structure, while still protecting the light-emitting element from moisture and oxygen penetration.

The dams 165a and 165b according to the first exemplary embodiment of the present disclosure may include an outer dam 165a disposed on the edge of the display panel 110, for example in the non-display area NA, and an inner dam 165b disposed inside the display panel 110, for example, in the display area AA.

In this case, the outer dam 165a may be referred to as a first dam, and the inner dam 165b may be referred to as a second dam.

The outer dam 165a may have an edge shape surrounding four sides of the display area AA, and is not limited thereto.

In FIG. 3, one outer dam 165a is illustrated, and the present disclosure is not limited thereto, and two or more outer dams 165a may be provided.

The inner dam 165b may have a bar shape or a rectangular shape parallel to a data line, for example, which is parallel to each other in one direction, and is not limited thereto.

A plurality of inner dams 165b may be disposed one by one in each subpixel column, and are not limited thereto.

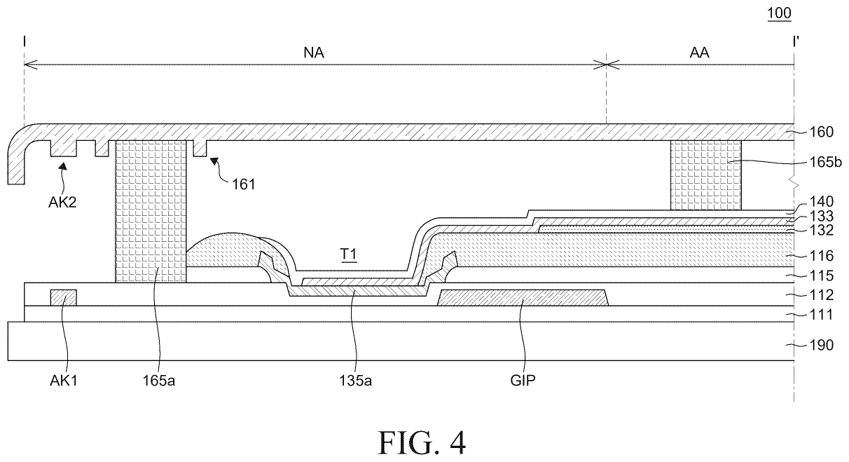

FIG. 4 is a cross-sectional view taken along the line I-I′ of FIG. 3.

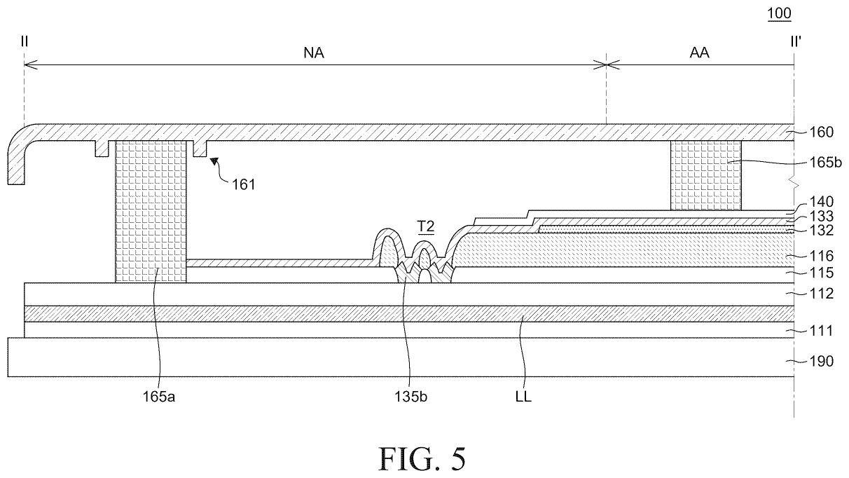

FIG. 5 is a cross-sectional view taken along the line II-II′ of FIG. 3.

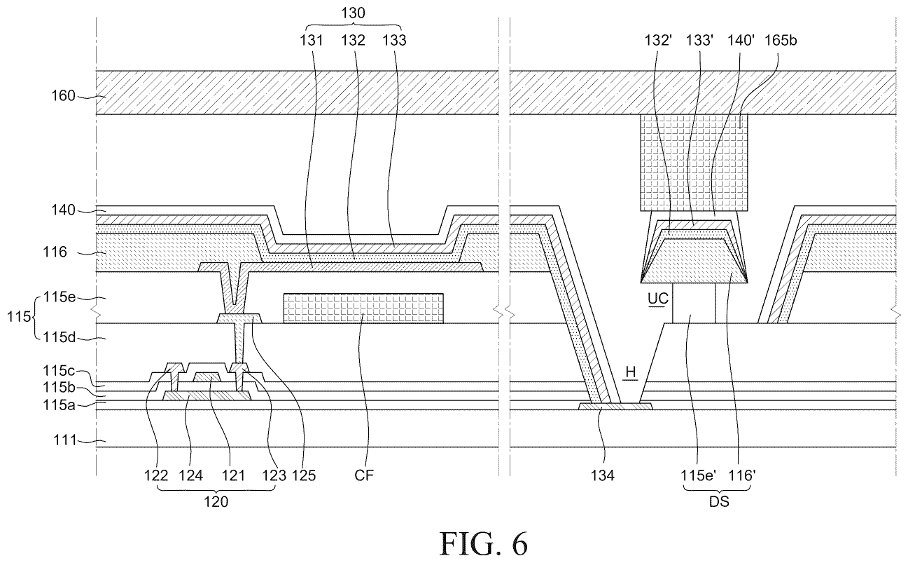

FIG. 6 is a cross-sectional view of one subpixel.

FIG. 4 shows a part of cross-sections of left and right sides of the display panel in which the gate pad part is located, and FIG. 5 shows a part of a cross-section of a lower side of the display panel in which the data pad part is located.

In FIGS. 4 and 5, for the convenience of description, a subpixel structure in the display area AA is omitted, and the subpixel structure may refer to FIG. 6. In FIGS. 4 and 5, for the convenience of description, a buffer layer 115a, a gate insulating layer 115b, and an interlayer insulating layer 115c are illustrated as one inorganic insulating layer 112.

Referring to FIGS. 4 to 6, the substrate 111 may be divided into a display area AA and a non-display area NA outside the display area AA.

The thin film transistor 120 and the light emitting element 130 may be disposed in the display area AA of the substrate 111.

The non-display area NA of the substrate 111 may include a GIP area.

A GIP circuit part GIP may be disposed in the GIP area of the substrate 111.

The substrate 111 serves to support and protect components of the display panel disposed thereon.

Recently, a flexible substrate 111 may be used with a flexible material having a flexible characteristic such as plastic.

The substrate 111 may be in the form of a film including one of a polyester-based polymer, a silicon-based polymer, an acrylic polymer, a polyolefin-based polymer, and a copolymer thereof.

A light shielding layer (not shown) may be disposed on the substrate 111.

The light shielding layer may be formed of a metal material having a light blocking function to prevent external light from entering a semiconductor layer 124 of the thin film transistor 120.

For example, the light-shielding layer may be formed of a single layer or a multilayer structure made of any one of opaque metals such as aluminum (Al), chromium (Cr), tungsten (W), titanium (Ti), nickel (Ni), neodymium (Nd), molybdenum (Mo), and copper (Cu) or an alloy thereof.

An auxiliary wiring 134 may be disposed on the same layer as the light shielding layer, and is not limited thereto, and may be disposed above the buffer layer 115a or on another layer.

The auxiliary wiring 134 may serve to transmit low potential power to the cathode 133 disconnected by a disconnection structure DS to be described later.

For example, a auxiliary wiring 134 may be disposed one by one in each subpixel column, and are not limited thereto.

Further, for example, the auxiliary wiring 134 may be disposed in a direction parallel to the data line, and is not limited thereto.

Meanwhile, in the non-display area NA, the link line LL may be disposed on the same layer as the light shielding layer, and is not limited thereto, and may be disposed on the buffer layer 115a or on a different layer.

The link line LL may be disposed at the lower side of the display panel in a direction of the flexible film. That is, for example, the link line LL may extend from a subpixel at the lower side of the display panel to a data pad part where the flexible film is connected, and is not limited thereto.

A buffer layer 115a may be disposed over the substrate 111 on which the light shielding layer, the auxiliary wiring 134, and the link line LL are disposed.

For example, the buffer layer 115a is a functional layer for protecting various electrodes and wirings from impurities such as moisture, oxygen, and alkali ions introduced from the substrate 111 or a lower portion. The buffer layer 115a may have a multilayer structure including a first buffer layer and a second buffer layer, and is not limited thereto.

For example, the buffer layer 115a may be made of silicon oxide (SiOₓ), silicon nitride (SiNₓ), or a multilayer structure thereof, and is not limited thereto. The buffer layer 115a may be eliminated according to the type of the thin film transistor 120.

The buffer layer 115a may include a contact hole exposing a part of the light shielding layer.

The buffer layer 115a may extend to the non-display area NA.

The thin film transistor 120 may be disposed over the buffer layer 115a.

The thin film transistor 120 in the display area AA may be a driving transistor. For convenience, FIG. 6 illustrates only the driving transistor 120. Other switching transistors, sensing transistors, and compensation circuits may also be included in the display device 100.

In this case, the driving transistor 120 may transmit a current transmitted through the power line to the anode 131 by a signal transmitted from the switching transistor, and control light emission by the current transmitted to the anode 131.

To this end, the driving transistor 120 may include a gate electrode 121, a semiconductor layer 124, a source electrode 122, and a drain electrode 123.

The switching transistor may be turned on by a gate pulse supplied to the gate line and transmit a data voltage supplied to the data line to the gate electrode 121 of the driving transistor 120.

The semiconductor layer 124 may be disposed on the buffer layer 115a.

The semiconductor layer 124 may be made of polysilicon (p-Si), and in this case, a predetermined region may be doped with impurities. Further, the semiconductor layer 124 may be made of amorphous silicon (a-Si) or various organic semiconductor materials such as pentacene. Furthermore, the semiconductor layer 124 may be made of an oxide semiconductor.

The semiconductor layer 124 may include a source region, a drain region, and a channel region between the source region and the drain region containing p-type or n-type impurities, and may further include a low-concentration doping region between the source region and the drain region adjacent to the channel region, and is not limited thereto.

The source region and the drain region are regions doped with impurities at a high concentration, and the source electrode 122 and the drain electrode 123 of the thin film transistor 120 may be connected to each other.

The impurity ions may use a p-type impurity or an n-type impurity, and the p-type impurity may be one of boron (B), aluminum (Al), gallium (Ga), and indium (In), and the n-type impurity may be one of phosphorus (P), arsenic (As), and antimony (Sb).

A gate insulating layer 115b may be disposed on the semiconductor layer 124. For example, the gate insulating layer 115b may be formed of an insulating inorganic material such as silicon oxide (SiOₓ) or silicon nitride (SiNₓ), or an insulating organic material.

The gate insulating layer 115b may extend to the non-display area NA. The gate electrode 121 may be disposed on the gate insulating layer 115b. The gate electrode 121 may be made of various conductive materials, for example, magnesium (Mg), aluminum (Al), nickel (Ni), chromium (Cr), molybdenum (Mo), tungsten (W), gold (Au), or an alloy thereof.

An interlayer insulating layer 115c may be disposed on the gate electrode 121. For example, the interlayer insulating layer 115c may be made of silicon oxide (SiOₓ), silicon nitride (SiNₓ), or a multilayer structure thereof.

The interlayer insulating layer 115c may extend to the non-display area NA.

The source electrode 122 and the drain electrode 123 may be disposed on the interlayer insulating layer 115c.

In this case, the source electrode 122 and the drain electrode 123 may be configured as a single layer or multilayer made of a metal material, such as aluminum (Al), molybdenum (Mo), chromium (Cr), gold (Au), titanium (Ti), nickel (Ni), neodymium (Nd), copper (Cu), or an alloy thereof, which are conductive metals. However, the present disclosure is not limited thereto.

Meanwhile, in the non-display area NA, the GIP circuit part GIP may be disposed on the substrate 111.

In addition, a first alignment key AK1 may be disposed at an edge of the non-display area NA.

The first alignment key AK1 may be formed of a metal material constituting the light shielding layer, the gate electrode 121, the source electrode 122, or the drain electrode 123 on an upper surface of the substrate 111.

The planarization layer 115 may be disposed over the thin film transistor 120 configured as described above. The planarization layer 115 may be referred to as an overcoat layer.

The planarization layer 115 may have a multilayer structure including at least two layers. For example, the planarization layer 115 may include a first planarization layer 115d and a second planarization layer 115e. For example, the first planarization layer 115d is disposed to cover the thin film transistor 120 and may expose a part of the source electrode 122 or the drain electrode 123 of the thin film transistor 120.

The planarization layer 115 may extend to the non-display area NA to cover the GIP circuit part GIP.

The planarization layer 115 may have a thickness of about 2 μm, and is not limited thereto.

The thin film transistor 120 may be classified into an inverted staggered structure and a coplanar structure according to positions of components constituting the thin film transistor 120. For example, in the case of the thin film transistor having the inverted staggered structure, the gate electrode may be located on the opposite side of the source electrode and the drain electrode based on the semiconductor layer. As shown in FIG. 6, in the thin film transistor 120 having the coplanar structure, the gate electrode 121 may be positioned on the same side as the source electrode 122 and the drain electrode 123 with respect to the semiconductor layer 124.

In FIG. 6, a thin film transistor 120 having the coplanar structure is illustrated, and is not limited thereto, and the present disclosure may include a thin film transistor having the inverted staggered structure. In addition, some of the thin film transistors 120 may have the coplanar structure, and other some of the thin film transistors 120 may have the inverted staggered structure.

A connection electrode 125 for electrically connecting the thin film transistor 120 and the light emitting element 130 may be disposed on the first planarization layer 115d. In addition, although not illustrated in FIG. 6, various metal layers serving as wires/electrodes such as signal lines may be disposed on the first planarization layer 115d.

In addition, a color filter CF may be disposed on the first planarization layer 115d, and is not limited thereto, and the color filter CF may be eliminated depending on the type of the light emitting element 130.

The color filter CF of each subpixel may have any one of red, green, and blue colors. In addition, in the case of a subpixel in which white is implemented, the color filter CF may not be disposed. The arrangement of red, green, and blue may be variously formed, and a black matrix capable of absorbing external light may be provided between the color filters CF.

In the case of the bottom emission type, the color filter CF may be located under the anode 131.

Further, a second planarization layer 115e may be disposed on the first planarization layer 115d and the connection electrode 125. In the display device 100 according to the first exemplary embodiment of the present disclosure, the planarization layer 115 is composed of two layers due to an increase in various signal lines as the display panel becomes high-resolution. Accordingly, it is difficult to dispose all wirings on one layer while securing a minimum gap, so an additional layer is formed. The addition of the additional layer (the second planarization layer 115e) may provide room for wiring arrangement, which may make it easier to design wiring/electrode arrangement. Further, when a dielectric material is used as the planarization layer 115 configured as a multilayer, the planarization layer 115 may be used for forming capacitance between metal layers. The second planarization layer 115e may be formed to expose a part of the connection electrode 125, and the drain electrode 123 of the thin film transistor 120 and the anode 131 of the light emitting element 130 may be electrically connected by the connection electrode 125.

A light emitting element 130 composed of an anode 131, an organic layer 132, and a cathode 133 may be disposed over the second planarization layer 115e.

The anode 131 may be disposed on the second planarization layer 115e.

The anode 131 is an electrode which serves to supply holes to the organic layer 132 and may be connected to the thin film transistor 120 through a contact hole formed in the planarization layer 115.

The display device 100 may be implemented in a top emission method or a bottom emission method. In the top emission method, a reflective layer made of an opaque conductive material having high reflectivity, for example, silver (Ag), aluminum (Al), gold (Au), molybdenum (Mo), tungsten (W), chromium (Cr), or an alloy thereof, may be added under the anode 131 so that light emitted from the organic layer 132 is reflected by the anode 131 and directed upward, that is, in the direction of the cathode 133. On the other hand, in the case of the bottom emission type, the anode 131 may be made of only a transparent conductive material such as indium tin oxide (ITO), indium zinc oxide (IZO), indium gallium zinc oxide (IGZO). Hereinafter, the description will be made on the assumption that the display panel of the present disclosure is a bottom emission type.

A bank 116 may be disposed on the anode 131 and the second planarization layer 115e. The bank 116 disposed on the anode 131 and the second planarization layer 115e may define a subpixel by partitioning an area that actually emits light, that is, an emission area. For example, after a photoresist is formed on the anode 131, the bank 116 may be formed through photolithography.

A fine metal mask (FMM) which is a deposition mask may be used to form the organic layer 132 of the light emitting element 130.

In addition, in order to prevent damage that may occur in contact with a deposition mask disposed on the bank 116 and maintain a predetermined distance between the bank 116 and the deposition mask, a spacer (not shown) composed of one of polyimide, photo acryl, and benzocyclobutene, which are transparent organic materials, may be disposed on the bank 116.

In this case, a part of the bank 116 in the emission area may be removed to expose a part of the anode 131.

The bank 116 may be disposed to extend to a part of the non-display area NA, and is not limited thereto.

In this case, for example, the bank 116 may extend to the non-display area NA and may be disposed on the planarization layer 115. For example, the bank 116 may extend to the non-display area NA and may be disposed on the planarization layer 115 on the GIP circuit part GIP.

The organic layer 132 may be disposed between the anode 131 and the cathode 133. The organic layer 132 serves to emit light. The organic layer 132 may include at least one of a hole injection layer (HIL), a hole transport layer (HTL), an emission layer, an electron transport layer (ETL), and an electron injection layer (EIL). Some components may be omitted depending on the structure or characteristics of the display device 100. Here, as the emission layer, an electroluminescent layer and an inorganic emission layer may be applied.

The hole injection layer is disposed on the anode 131 to facilitate the injection of holes.

The hole transport layer is disposed on the hole injection layer to smoothly transmit holes to the emission layer.

The emission layer is disposed on the hole transport layer and includes a material capable of emitting light of a specific color to emit light of a specific color. Further, the light emitting material may be formed using a phosphorescent material or a fluorescent material.

An electron injection layer may be further disposed on the electron transport layer. The electron injection layer is an organic layer that facilitates injection of electrons from the cathode 133 and may be omitted depending on the structure and characteristics of the display device 100.

In the meantime, when an electron blocking layer and/or a hole blocking layer for blocking a flow of holes or electrons are further disposed at a position adjacent to the light emitting layer, it is possible to prevent the electron from moving from the light emitting layer when injected into the light emitting layer and passing through the adjacent hole transport layer or prevent the hole from moving from the light emitting layer when injected into the light emitting layer and passing through the adjacent electron transport layer, thereby improving luminous efficiency.

The organic layer 132 may be disposed to extend to a part of the non-display area NA, and is not limited thereto.

For example, the organic layer 132 may extend to the non-display area NA and may be disposed on the bank 116. Further, for example, the organic layer 132 may extend to the non-display area NA and may be disposed on the bank 116 above the GIP circuit part GIP.

The cathode 133 may be disposed on the organic layer 132.

The cathode 133 serves to supply electrons to the organic layer 132. Since the cathode 133 needs to supply electrons, the cathode 133 may be made of a metal material such as magnesium or silver-magnesium, which are conductive materials having a low work function, and is not limited thereto.

The cathode 133 may extend to a part of the non-display area NA. For example, the cathode 133 may be disposed to extend to a part of the non-display area NA to cover an end of the organic layer 132. However, the present disclosure is not limited thereto.

Although not illustrated, a capping layer may be disposed on the cathode 133. The capping layer protects the light emitting element 130 and may serve to efficiently discharge light generated from the organic layer 132 toward the outside.

The protective layer 140 may be disposed on the cathode 133.

The protective layer 140 may be an inorganic layer, and in this case, may be made of silicon oxide (SiOₓ), silicon nitride (SiNₓ), or a multi-layer thereof.

The protective layer 140 may extend to the non-display area NA.

The protective layer 140 may be disposed to cover all or a part of the cathode 133.

For example, the protective layer 140 may be disposed at a lower side of the display panel to cover a part of the cathode 133 (see FIG. 5), and disposed at the left, right, or upper side of the display panel to cover the entire cathode 133 (see FIG. 4).

The display panel according to the first exemplary embodiment of the present disclosure is characterized in that at least a portion of at least one layer of the planarization layer 115 and the inorganic insulating layer 112 in the non-display area NA is selectively removed to form trenches T1 and T2.

A first trench T1 may be formed by removing a portion of the planarization layer 115 and the inorganic insulating layer 112 of the non-display area NA from the left, right, or upper side of the display panel (see FIG. 4).

In this case, only a partial thickness of the inorganic insulating layer 112 may be selectively removed, and is not limited thereto.

Further, for example, the first trench T1 may surround three sides of the left, right, and upper sides of the display panel, and is not limited thereto.

A first pattern 135a made of the same transparent conductive material as the anode 131 may be disposed on a lower surface of the first trench T1, and is not limited thereto and may be made of another conductive material.

Further, a part of the bank 116 is removed from the first trench T1 in which the first pattern 135a is disposed, such that the first trench T1 may be exposed. The bank 116 may be configured to cover both ends of the first pattern 135a disposed on the side surface of the first trench T1.

Further, the cathode 133 may extend to the non-display area NA to cover a partial area of the exposed first trench T1. The cathode 133 may cover a part of the exposed first pattern 135a.

In addition, the protective layer 140 may extend to the non-display area NA to cover another partial area of the first trench T1. The protective layer 140 may cover another part of the exposed first pattern 135a which is not covered by the cathode 133.

A portion of the planarization layer 115 in the non-display area NA is removed from the lower side of the display panel to form a second trench T2 (see FIG. 5).

In FIG. 5, a case where two second trenches T2 are provided is illustrated as an example, but the present disclosure is not limited thereto.

A second pattern 135b made of the same transparent conductive material as the anode 131 may be disposed on a lower surface of the second trench T2, and is not limited thereto and may be made of another conductive material.

Further, a part of the bank 116 is removed from the second trench T2 in which the second pattern 135b is disposed, such that the second trench T2 may be exposed. The bank 116 may be disposed to cover both ends of the second pattern 135b disposed on the side surface of the second trench T2.

Further, the cathode 133 may extend to the non-display area NA to cover the exposed second trench T2 and the bank 116. The cathode 133 may cover the second pattern 135b.

The optical member 190 according to the first embodiment of the present disclosure may be disposed on the rear surface of the display panel configured as described above, that is, the rear surface of the substrate 111.

Further, an adhesive layer (not shown) which is transparent and has adhesive properties may be interposed between the substrate 111 and the optical member 190.

At this time, the optical member 190 serves to improve the visibility of the display device 100 by suppressing the reflection of external light and minimize the loss of light emitted from the light emitting element 130 to the outside.

Although not shown in detail, the optical member 190 may include a phase retardation layer and a linear polarizer.

For example, the phase retardation layer may be configured by a quarter wave plate (QWP) that generates a phase retardation of λ/4.

Further, for example, a protective layer may be provided on the linear polarizer.

In addition, a surface treatment layer including an anti-reflection film (AR film) may be positioned on the protective layer. The antireflection film may be formed through wet coating or dry sputtering.

The display device 100 according to the first exemplary embodiment of the present disclosure configured as described above is characterized in that dams 165a and 165b are disposed at the edges and inside of the display panel.

Further, in the first embodiment of the present disclosure, the back cover 160 is vacuum-bonded onto the display panel, on which the dams 165a and 165b are disposed, to seal the display panel.

Therefore, the adhesive layer and the encapsulation substrate required for the encapsulation can be eliminated, thereby reducing the consumption of raw materials for the adhesive layer and the encapsulation substrate, and reducing the process cost by omitting the process for encapsulation. In addition, the removing of the adhesive layer and the encapsulation substrate provides an effect of protecting the light emitting element 130 from moisture permeation and oxygen permeation while minimizing the thickness of the encapsulation layer compared to the existing encapsulation structure.

The dams 165a and 165b according to the first exemplary embodiment of the present disclosure may include an edge and inside of the display panel, that is, an outer dam 165a disposed in the non-display area NA, and an inner dam 165b disposed inside the display panel, that is, for example, in the display area AA.

The outer dam 165a may have an edge shape surrounding four sides of the display area AA.

The inner dam 165b may have a bar shape or a rectangular shape parallel to the data line, for example, which is parallel to the data line in one direction, and is not limited thereto, and may have a bar shape or a rectangular shape parallel to the gate line.

A plurality of inner dams 165b may be disposed one by one in each subpixel column, and are not limited thereto.

For example, the dams 165a and 165b may serve to delay lateral moisture permeation. Further, the dams 165a and 165b may serve to maintain a constant gap between the back cover 160 and the substrate 111.

For example, the outer dam 165a may have a width of about 10 μm to prevent lateral moisture permeation. However, the present disclosure is not limited thereto.

An upper surface of the outer dam 165a may be in contact with the lower surface of the back cover 160, and a lower surface thereof may be in contact with the upper surface of the inorganic insulating layer 112. Further, a side surface of the outer dam 165a may be in contact with a side surface of the planarization layer 115 and/or the bank 116.

For example, the dams 165a and 165b may further include a desiccant such as a getter in the sealant. The desiccant may include calcium oxide.

The sealant may be made of thermosetting or ultraviolet (UV) curable resin. For example, the sealant may be composed of an epoxy resin or an acrylic resin to which a thermosetting accelerator and/or a photoinitiator is added. The sealant may reinforce a bonding force between the back cover 160 and the inorganic insulating layer 112 by bonding edges thereof.

The desiccant may be particles having hygroscopicity and absorb moisture and oxygen from the outside to minimize the penetration of moisture and oxygen into the display area AA.

In addition, the dams 165a and 165b may further include spacers for maintaining the cell gap.

For example, the back cover 160 may serve to prevent front moisture penetration. Further, the back cover 160 is formed to have a thickness of about 7 μm to prevent the substrate 111 from sagging and protect the display panel from an external impact.

An edge of the back cover 160 may be bent toward the substrate 111 and may have a groove formed in an inner surface thereof, and is not limited thereto.

Further, for example, the back cover 160 may further include a dam bank 161 for defining an application area of the sealant. The sealant may be diffused under pressure when the back cover 160 is bonded onto the display panel. The dam bank 161 is formed in one or more of the substrate 111 and the back cover 160 at a position in contact with both edges of the drawing line of the sealant to serve to limit diffusion of the sealant.

When the dam bank 161 is formed on the back cover 160, the dam bank 161 may be integrally formed with the back cover 160 by etching the metal constituting the back cover 160, and is not limited thereto.

One or more dam banks 161 may be provided on a side of the outer dam 165a.

Further, a first alignment key AK1 may be formed over the substrate 111 in the non-display area NA.

The first alignment key AK1 may be formed of a metal material which configures a light shielding layer, a gate electrode 121, a source electrode 122, or a drain electrode 123 over the substrate 111.

The first alignment key AK1 may be used in a module process of the display device 100.

For example, the first alignment key AK1 may be used in a bezel printing process for preventing wirings or the like in a bezel area from being visible in order to improve the user's visual perception, in an optical member 190 attaching process, in a laser cutting process of the optical member 190, in dams 165a and 165b dispensing process, and in a bonding process of the back cover 160 and the display panel.

For the bonding process of the back cover 160 and the display panel, a second alignment key AK2 may be formed on the back cover 160 facing the first alignment key AK1.

For example, the second alignment key AK2 may be integrally formed with the back cover 160 by etching the metal constituting the back cover 160, and is not limited thereto.

The second alignment key AK2 may have an embossed shape, and is not limited thereto.

Meanwhile, during the process of applying the inner dam 165b to the display area AA, a crack may occur in the protective layer 140 due to a getter or the like in the inner dam 165b. If a crack occurs in the protective layer 140, reliability defects may occur in the light emitting element 130 due to moisture or oxygen.

Accordingly, in the first embodiment of the present disclosure, the disconnection structure DS is formed on the upper portion of the substrate 111 corresponding to the inner dam 165b to block the propagation of cracks in the protective layer 140 caused by the desiccant in the inner dam 165b. As described above, according to the present disclosure, it is possible to improve the reliability of the display panel and improve the lifespan of the light emitting element 130 by blocking oxygen or moisture from penetrating into the light emitting element 130. In addition, power consumption may be reduced accordingly, and in this case, greenhouse gas emissions may be reduced by reducing the use of fossil fuels for power generation, thereby implementing environment/social/governance (ESG).

The disconnection structure DS may be disposed at a position opposite the inner dam 165b. For example, the disconnection structure DS of the present disclosure may be configured by selectively removing a portion of the bank 116 and the second planarization layer 115e of the display area AA. However, the present disclosure is not limited thereto. A portion of two layers sequentially stacked among the bank 116, the second planarization layer 115e, the first planarization layer 115d, the interlayer insulating layer 115c, the gate insulating layer 115b, and the buffer layer 115a may be selectively removed.

For example, the disconnection structure DS of the present disclosure configured by the bank pattern 116′ and the second planarization layer pattern 115e′ made of materials respectively configuring the bank 116 and the second planarization layer 115e may be disposed below the inner dam 165b. An organic layer pattern 132′ , a cathode pattern 133′ , and a protective layer pattern 140′ separated from each of the organic layer 132, the cathode 133, and the protective layer 140 may be disposed above the disconnection structure DS.

The disconnection structure DS of the present disclosure may include an undercut UC. That is, for example, the second planarization layer pattern 115e′ under the bank pattern 116′ is further etched inward than the bank pattern 116′ to form the undercut UC in the form of eaves. By the undercut UC, each of the organic layer 132, the cathode 133, and the protective layer 140 on the left and right sides of the disconnection structure DS may be separated (disconnected) from the organic layer pattern 132′ , the cathode pattern 133′ , and the protective layer pattern 140′ .

The inner dam 165b for maintaining a cell gap may be disposed on the disconnection structure DS of the present disclosure.

The disconnection structure DS may be disposed side by side in one direction, like the inner dam 165b, and is not limited thereto.

In addition, a hole H may be disposed in at least one side of the disconnection structure DS.

For example, the hole H may be formed by additionally removing a portion of the first planarization layer 115d, the interlayer insulating layer 115c, the gate insulating layer 115b, and the buffer layer 115a from one side of the disconnection structure DS, and is not limited thereto.

FIG. 6 illustrates an example in which the disconnection structure DS and the hole H are formed in a single column, but the present disclosure is not limited thereto. The disconnection structure DS and the hole H may be formed in two or more columns, respectively, and the present disclosure is not limited to the number of columns of the disconnection structure DS and the hole H.

The disconnection structure DS and the hole H may be configured one by one for each subpixel, and are not limited thereto.

The hole H may expose at least a part of the auxiliary wiring 134.

Side surfaces of the bank 116 and the second planarization layer 115e may be exposed through the left and right sidewalls of the disconnection structure DS. The organic layer 132, the cathode 133, and the protective layer 140 may be disposed to cover the exposed side surfaces of the bank 116 and the second planarization layer 115e. Meanwhile, in the hole H, side surfaces of the first planarization layer 115d, the interlayer insulating layer 115c, the gate insulating layer 115b, and the buffer layer 115a which are exposed may be covered by the organic layer 132, the cathode 133, and the protective layer 140.

Accordingly, the cathode 133 disposed in the hole H is electrically connected to the auxiliary wiring 134 to receive low potential power even to the disconnection of the cathode 133.

FIG. 7 is a plan view of a display device according to a second embodiment of the present disclosure.

The only difference between a display device 200 of the second embodiment of FIG. 7 and the display device 100 of the first embodiment of FIGS. 1 to 6 described above is a placement direction of an inner dam, but the other configuration is substantially the same, so that a redundant description will be omitted. In addition, the same reference numerals will be used for the same components. Hereinafter, description of the same reference numerals may refer to FIG. 1 through FIG. 6.

Referring to FIG. 7, the display device 200 according to the second exemplary embodiment of the present disclosure may include a display panel 210, a flexible film 170, and a printed circuit board 180.

Further, the display device 200 according to the second exemplary embodiment of the present disclosure may include an outer dam 165a disposed in the non-display area NA of the display panel 210 and an inner dam 265b disposed in the display area AA of the display panel 210.

The outer dam 165a may have an edge shape surrounding four sides of the display area AA.

On the other hand, the inner dam 265b may have a bar shape or a rectangular shape parallel to the gate line, for example, parallel to one direction, and is not limited thereto.

A plurality of inner dams 265b may be disposed one by one in each subpixel row, and are not limited thereto.

Meanwhile, a disconnection structure (DS of FIG. 6) may be disposed on the substrate 111 corresponding to the inner dam 265b.

The disconnection structure DS may be disposed at a position opposite to the inner dam 265b. Accordingly, the disconnection structure DS may be disposed side by side in the same gate line direction as the inner dam 265b. In addition, the auxiliary wiring (134 of FIG. 6) may be disposed in a direction parallel to the gate line.

The display device 200 according to the second exemplary embodiment of the present disclosure configured as described above is characterized in that the back cover (160 of FIG. 6) is vacuum-bonded onto the display panel 210 on which the dams 165a and 265b are disposed to seal the display panel 210.

Meanwhile, according to the present disclosure, a buffer structure may be provided on the back cover to prevent the substrate from being damaged by pressing the substrate by vacuum bonding of the back cover and the substrate, which will be described in detail with reference to the drawings.

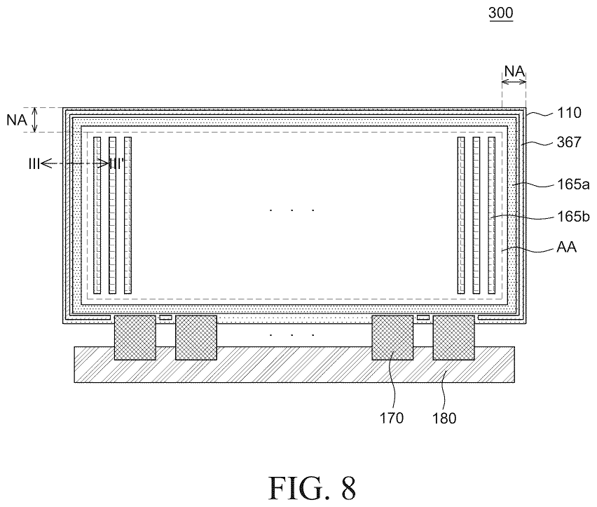

FIG. 8 is a plan view of a display device according to a third embodiment of the present disclosure.

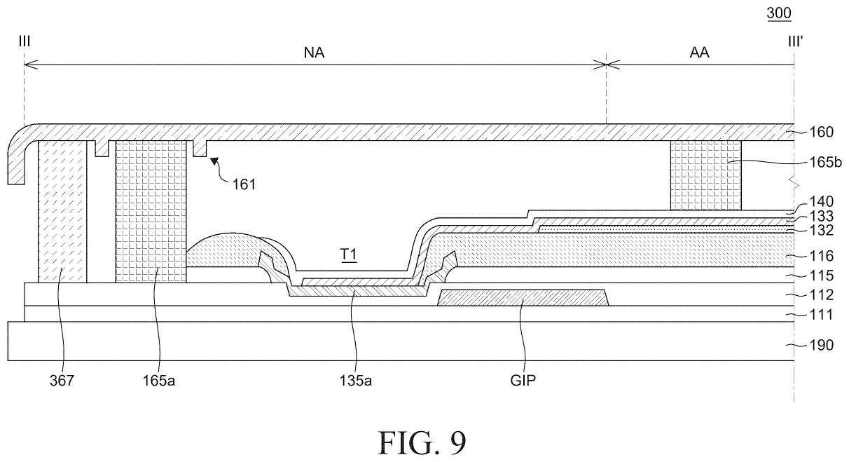

FIG. 9 is a cross-sectional view taken along the line III-III′ of FIG. 8.

The only difference between a display device 300 of the third embodiment of FIGS. 8 and 9 and the display device 100 of the first embodiment of FIGS. 1 to 6 described above is that a buffer structure is provided on a back cover, and other configurations are substantially the same, so that a redundant description will be omitted. The same components will be denoted by the same reference numerals. Hereinafter, description of the same reference numerals may refer to FIG. 1 through FIG. 7.

Referring to FIGS. 8 and 9, a display device 300 according to the third embodiment of the present disclosure may include a display panel 110, a flexible film 170, and a printed circuit board 180.

Further, the display device 300 according to the third exemplary embodiment of the present disclosure may include an outer dam 165a disposed in the non-display area NA of the display panel 110 and an inner dam 165b disposed in the display area AA of the display panel 110.

The outer dam 165a may have an edge shape surrounding four sides of the display area AA.

The inner dam 165b may have a bar shape or a rectangular shape parallel to the data line, for example, which is parallel to the data line in one direction, and is not limited thereto, and may have a bar shape or a rectangular shape parallel to the gate line.

Meanwhile, a disconnection structure (DS of FIG. 6) may be disposed on the substrate 111 corresponding to the inner dam 165b.

The display device 300 according to the third exemplary embodiment of the present disclosure configured as described above is characterized in that the back cover 160 is vacuum-bonded on the upper portion of the display panel 110 on which the dams 165a and 165b are disposed to seal the display panel 110.

The third embodiment of the present disclosure is characterized in that the back cover 160 is provided with a buffer structure 367 to prevent the substrate 111 from being damaged by the pressing of the substrate 111 by the vacuum bonding of the back cover 160 and the substrate 111.

The back cover 160 may be prevented from being in direct contact with the substrate 111 by the buffer structure 367 between the back cover 160 and the substrate 111.

The buffer structure 367 may be provided on a lower surface of the back cover 160 outside the outer dam 165a.

For example, the buffer structure 367 may be formed of a resin such as epoxy or acrylic, and is not limited thereto.

The buffer structure 367 may be spaced apart from the outer dam 165a by a predetermined distance.

For example, the separation distance may have a value greater than or equal to about 260 μmin consideration of an alignment error during vacuum bonding with the application tolerance of the outer dam 165a. When the width of the outer dam 165a is 2.5 mm, it may be calculated as the sum of the alignment error of 10 μm during vacuum bonding and the application tolerance of about 10%, 250 μm.

The buffer structure 367 may have an edge shape surrounding the outer dam 165a except for an area to which the flexible film 170 is connected.

An upper surface of the buffer structure 367 may be in contact with the lower surface of the back cover 160, and a lower surface may be in contact with the upper surface of the inorganic insulating layer 112.

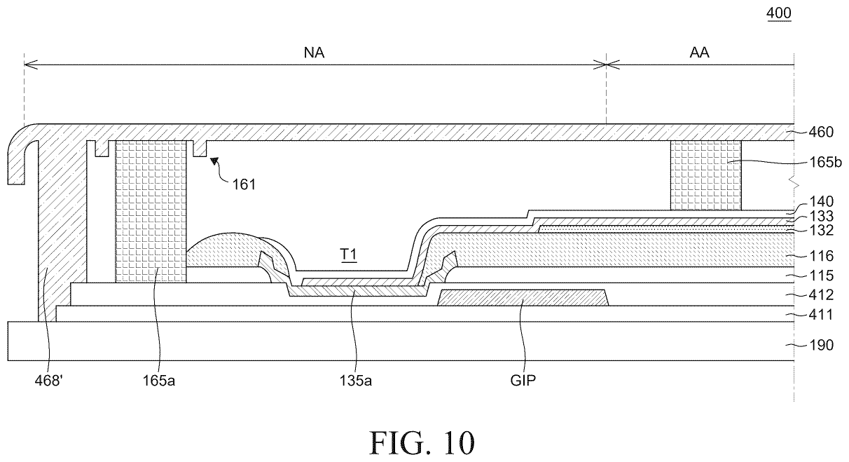

FIG. 10 is a cross-sectional view of a display device according to a fourth embodiment of the present disclosure.

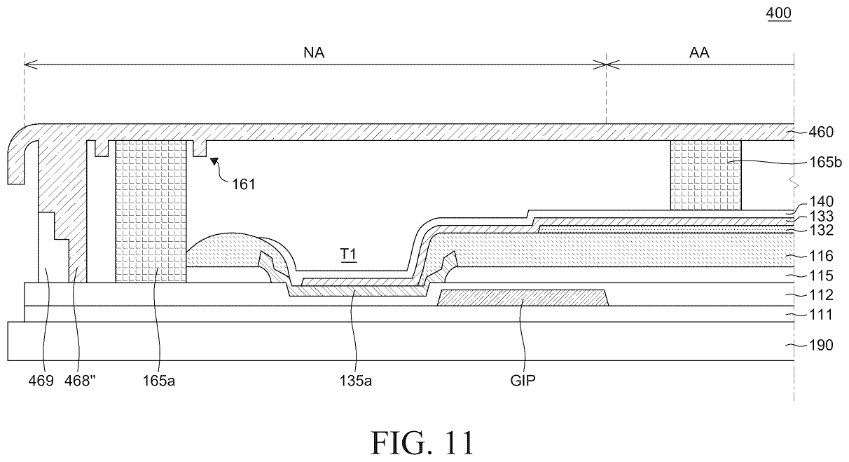

FIG. 11 is a cross-sectional view illustrating another example of a display device according to the fourth embodiment of the present disclosure.

A display device 400 according to the fourth embodiment of FIGS. 10 and 11 is substantially identical in configuration to the display device 300 of the third embodiment of FIGS. 8 and 9 described above, except for a shape of a buffer structure and a lower structure corresponding thereto. Therefore, repeated descriptions of the identical components will be omitted. In addition, the same reference numerals will be used for the same components. Hereinafter, description of the same reference numerals may refer to FIGS. 1 to 9.

Referring to FIGS. 10 and 11, the display device 400 according to the fourth embodiment of the present disclosure may include an outer dam 165a disposed in the non-display area NA of the display panel (110 of FIG. 8) and an inner dam 165b disposed in the display area AA of the display panel 110.

Further, the display device 400 according to the fourth embodiment of the present disclosure is characterized in that the back cover 460 is vacuum-bonded on the upper portion of the display panel 110 on which the dams 165a and 165b are disposed to seal the display panel 110.

The fourth embodiment of the present disclosure is characterized in that the back cover 460 is provided with buffer structures 468′ and 468″ to prevent the substrate 111 from being damaged by pressing the substrate 111 by vacuum bonding of the back cover 460 and the substrate 111. The back cover 460 may be prevented from being in direct contact with the substrate 111 by the buffer structures 468′ and 468″ between the back cover 460 and the substrate 111.

The buffer structures 468′ and 468″ may be provided on the bottom surface of the back cover 460 outside the outer dam 165a. The buffer structures 468′ and 468″ may be integrally formed with the back cover 460, and are not limited thereto. The buffer structures 468′ and 468″ may be formed in an embossed shape on the back cover 460.

The buffer structures 468′ and 468″ may be spaced apart from the outer dam 165a by a predetermined distance.

The buffer structures 468′ and 468″ may have an edge shape surrounding the outer dam 165a except for an area to which the flexible film 170 of FIG. 8 is connected.

The buffer structures 468′ and 468″ may have an upper surface in contact with a lower surface of the back cover 460 and a lower surface in contact with an upper surface of the inorganic insulating layer 112 or the optical member 190.

The buffer structures 468′ and 468″ may have one side surface as a stepped structure, and are not limited thereto. Therefore, the buffer structures 468′ and 468″ may have a width smaller than a width of a top surface of the inorganic insulating layer 112 or a top surface of the optical member 190 which is in contact with a bottom surface of the back cover 460.

The buffer structure 468′ of FIG. 10 is a case where the inner surface of the buffer structure 468′ has a stepped structure, and side surfaces of the substrate 411 and the inorganic insulating layer 412 may be partially etched inward to correspond to the stepped structure. That is, for example, the substrate 411 of FIG. 10 may be etched inward than the substrate according to other embodiments, and the inorganic insulating layer 412 may be etched inward more than the substrate 411.

Further, the buffer structure 468″ of FIG. 11 is a case where the outer surface of the buffer structure 468″ has a stepped structure. Thus, the dummy pattern 469 may be disposed on the upper surface of the inorganic insulating layer 112 corresponding to the stepped structure. That is, for example, the dummy pattern 469 has a shape in which the inner surface of the dummy pattern 469 corresponds to the stepped structure of the outer surface of the buffer structure 468″ and may be configured by a part of the planarization layer 115 and/or the bank 116 of the display area AA which extends to the non-display area NA, but the present disclosure is not limited thereto, and may be configured in a separate configuration different from the planarization layer 115 and the bank 116.

Even though it is not illustrated, a part of the substrate 111 and/or the inorganic insulating layer 112 may be etched in a form corresponding to the stepped structure of the buffer structure 468″.

The exemplary embodiments of the present disclosure can also be described as follows:

A display device according to an exemplary embodiment of the present disclosure may include a substrate divided into a display area and a non-display area, an inorganic insulating layer and a planarization layer disposed over the substrate, a light emitting element disposed over the planarization layer and configured by an anode, an organic layer, and a cathode, an outer dam disposed over the substrate in the non-display area to surround the display area, a plurality of inner dams disposed in the display area, and a back cover which maintains a gap by the outer dam and the inner dam and is vacuum-bonded to the substrate.

The outer dam may have an edge shape surrounding four sides of the display area, and the inner dam may be disposed one by one in each subpixel column and has a bar shape or a rectangular shape parallel to a data line or a gate line.

The upper surface of the outer dam may be in contact with the lower surface of the back cover, and the lower surface may be in contact with the upper surface of the inorganic insulating layer, and the planarization layer may extend to the non-display area to be in contact with the side surface of the outer dam.

The display device may further comprise a trench configured by removing at least a portion of at least one of the planarization layers and the inorganic insulating layer of the non-display area, the trench may be disposed between the outer dam and the inner dam.

The outer dam and the inner dam may include a desiccant and a spacer in a sealant, and the desiccant may include calcium oxide.

The display device may further comprise at least one dam bank integrally formed with the back cover on a side surface of the outer dam, a first alignment key disposed above the substrate in the non-display area and a second alignment key disposed on the back cover opposite to the first alignment key, the second alignment key may be integrally formed with the back cover.

The display device may further comprise a bank disposed on the planarization layer and a disconnection structure disposed on the substrate corresponding to the inner dam and including a bank pattern separated from the bank and a second planarization layer pattern separated from the second planarization layer, the planarization layer may comprise a first planarization layer and a second planarization layer disposed on the first planarization layer.

An organic layer pattern, a cathode pattern, and a protective layer pattern separated from each of the organic layer, the cathode, and the protective layer may be disposed above the disconnection structure.

The second planarization layer pattern under the bank pattern may be further etched inward than the bank pattern to constitute an undercut in the form of eaves, and the organic layer, the cathode, and the protective layer on the left and right sides of the disconnection structure may be separated from the organic layer pattern, the cathode pattern, and the protective layer pattern, respectively, by the undercut.

The display device may further comprise an auxiliary wiring which is disposed in the subpixel and transmits a low potential power to the cathode and at one side of the disconnection structure, a hole configured by removing a portion of the first planarization layer and the inorganic insulating layer, the hole may expose at least a portion of the auxiliary wiring.

The cathode disposed inside the hole may be electrically connected to the exposed auxiliary wiring.

Side surfaces of the bank and the second planarization layer may be exposed through left and right sidewalls of the disconnection structure, the organic layer, the cathode, and the protective layer may be disposed to cover the exposed bank and the side surfaces of the second planarization layer, and the organic layer, the cathode, and the protective layer may cover the side surfaces of the exposed first planarization layer and the inorganic insulating layer in the hole.

The display device may further comprise a buffer structure disposed outside the outer dam and spaced apart from the outer dam by a predetermined distance.

The buffer structure may be integrally formed with the back cover in an embossed shape, and the buffer structure may have at least one side having a stepped structure.

An inner side of the buffer structure may have the stepped structure, and side surfaces of the substrate and the inorganic insulating layer maybe partially etched inward corresponding to the stepped structure.

An outer side of the buffer structure may have the stepped structure, and a dummy pattern may be disposed on the upper surface of the inorganic insulating layer, an inner side of the dummy pattern having a shape corresponding to the stepped structure.

The dummy pattern may be composed of a planarization layer and/or a bank of the display area.

A part of the substrate and/or the inorganic insulating layer may be etched in a form corresponding to the buffer structure.

Although the exemplary embodiments of the present disclosure have been described in detail with reference to the accompanying drawings, the present disclosure is not limited thereto and may be embodied in various forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate divided into a display area and a non-display area;
an inorganic insulating layer and a planarization layer disposed over the substrate;
a light emitting element disposed over the planarization layer and comprising an anode, an organic layer, and a cathode;
an outer dam disposed over the substrate in the non-display area so as to enclose the display area;
a plurality of inner dams disposed in the display area; and
a back cover which maintains a gap by the outer dam and the plurality of inner dams, wherein the back cover is vacuum-bonded to the substrate.

2. The display device according to claim 1, wherein the outer dam has an edge shape surrounding four sides of the display area,
wherein the plurality of inner dams is disposed one by one in each subpixel column, and
wherein the plurality of inner dams has a bar shape or a rectangular shape parallel to a data line or a gate line.

3. The display device according to claim 1, wherein an upper surface of the outer dam is in contact with a lower surface of the back cover,
wherein the lower surface is in contact with the upper surface of the inorganic insulating layer, and
wherein the planarization layer extends to the non-display area to be in contact with a side surface of the outer dam.

4. The display device according to claim 1, further comprising:
a trench configured by removing at least a portion of at least one of the planarization layers and the inorganic insulating layer of the non-display area,
wherein the trench is disposed between the outer dam and the inner dam.

5. The display device according to claim 1, wherein each of the outer dam and the inner dam comprises a desiccant and a spacer in a sealant, and
wherein the desiccant comprises calcium oxide.

6. The display device according to claim 1, further comprising:
at least one dam bank integrally formed with the back cover on a side surface of the outer dam;
a first alignment key disposed above the substrate in the non-display area; and
a second alignment key disposed on the back cover opposite to the first alignment key,
wherein the second alignment key is integrally formed with the back cover.

7. The display device according to claim 1, further comprising:
a bank disposed on the planarization layer; and
a disconnection structure disposed on the substrate corresponding to the inner dam,
wherein the disconnection structure comprises a bank pattern separated from the bank and a second planarization layer pattern separated from the second planarization layer, and
wherein the planarization layer comprises a first planarization layer and the second planarization layer disposed on the first planarization layer.

8. The display device according to claim 7, wherein an organic layer pattern, a cathode pattern, and a protective layer pattern is separated from each of the organic layer, the cathode, and the protective layer, and
wherein the organic layer pattern, the cathode pattern, and the protective layer pattern is disposed above the disconnection structure.

9. The display device according to claim 8, wherein the second planarization layer pattern under the bank pattern is further etched inward so that the bank pattern constitutes an undercut in a form of eaves, and
wherein the organic layer, the cathode, and the protective layer disposed on a left side and on a right side of the disconnection structure are separated from the organic layer pattern, the cathode pattern, and the protective layer pattern, respectively, by the undercut.

10. The display device according to claim 7, further comprising:
an auxiliary wiring disposed in a subpixel, wherein the auxiliary wiring transmits a low potential power to the cathode; and
at one side of the disconnection structure, a hole configured by removing a portion of the first planarization layer and the inorganic insulating layer, and
wherein the hole exposes at least a portion of the auxiliary wiring.

11. The display device according to claim 10, wherein the cathode disposed inside the hole is electrically connected to the exposed auxiliary wiring.

12. The display device according to claim 10, wherein side surfaces of a bank and side surfaces of a second planarization layer are exposed through a left sidewall and a right sidewall of the disconnection structure,
wherein the organic layer, the cathode, and a protective layer is disposed to cover the exposed bank and the side surfaces of the second planarization layer, and
wherein the organic layer, the cathode, and the protective layer cover the side surfaces of the exposed first planarization layer and the side surfaces of the inorganic insulating layer in the hole.

13. The display device according to claim 1, further comprising:
a buffer structure disposed outside the outer dam, wherein the buffer is spaced apart from the outer dam by a predetermined distance.

14. The display device according to claim 13, wherein the buffer structure is integrally formed with the back cover in an embossed shape, and
wherein the buffer structure has at least one side having a stepped structure.

15. The display device according to claim 14, wherein an inner side of the buffer structure has the stepped structure, and
wherein side surfaces of the substrate and side surfaces of the inorganic insulating layer are partially etched inward corresponding to the stepped structure.

16. The display device according to claim 14, wherein an outer side of the buffer structure has the stepped structure,
wherein a dummy pattern is disposed on an upper surface of the inorganic insulating layer, and
wherein an inner side of the dummy pattern has a shape corresponding to the stepped structure.

17. The display device according to claim 16, wherein the dummy pattern comprises a planarization layer and/or a bank of the display area.

18. The display device according to claim 14, wherein a part of the substrate and/or the inorganic insulating layer is etched in a form corresponding to the buffer structure.
